(19) United States
(12) Patent Application Publication
(10) Pub. No.: US 2018/0090466 A1
(43) Pub. Date: Mar. 29, 2018

(54) SEMICONDUCTOR DEVICE PACKAGE AND METHOD OF MANUFACTURING THE SAME

(71) Applicant: Advanced Semiconductor Engineering, Inc., Kaohsiung (TW)

(72) Inventor: Wen-Chi HUNG, Kaohsiung (TW)

(73) Assignee: Advanced Semiconductor Engineering, Inc., Kaohsiung (TW)

(21) Appl. No.: 15/280,837

(22) Filed: Sep. 29, 2016

(51) Int. Cl. H01L 25/065; H01L 23/552; H01L 23/31; H01L 23/29; H01L 21/56; H01L 21/48

(52) U.S. Cl. CPC H01L 25/0655; H01L 23/552; H01L 23/3135; H01L 21/4871; H01L 21/56; H01L 21/4846; H01L 23/29

(57) ABSTRACT

A semiconductor device package includes a substrate, electronic components disposed over a surface of the substrate, an encapsulant encapsulating the electronic components, and a conductive compartment structure. The conductive compartment structure separates at least one first electronic component from at least one second electronic component. The conductive compartment structure includes a first portion and a second portion, the second portion includes a first end connected to the first portion and a second end exposed from a lateral surface of the encapsulant, and a width of the second portion is less than a width of the first portion.

### BACKGROUND

### 1. Technical Field

The present disclosure relates to a semiconductor device package and method of manufacturing the same, and more particularly, to a semiconductor device package including a conductive compartment structure with smaller width at an end portion.

### 2. Description of the Related Art

A semiconductor device package can include electronic components working at relative high frequency, such as radio frequency integrated circuits (RFICs), which may generate electromagnetic interference (EMI) or may be susceptible to EMI. Some semiconductor device packages incorporate structures to reduce effects of EMI.

### SUMMARY

In one or more embodiments, a semiconductor device package includes a substrate, electronic components disposed over a surface of the substrate, an encapsulant encapsulating the electronic components, and a conductive compartment structure. The conductive compartment structure separates at least one first electronic component from at least one second electronic component. The conductive compartment structure includes a first portion and a second portion, the second portion includes a first end connected to the first portion and a second end exposed from a lateral surface of the encapsulant, and a width of the second portion is less than a width of the first portion.

In one or more embodiments, a semiconductor device package includes a substrate, electronic components disposed over a surface of the substrate, an encapsulant covering at least a portion of the electronic components, and a conductive compartment structure. The conductive compartment structure separates a first electronic component of the portion of the electronic components covered by the encapsulant from a second electronic component. The conductive compartment structure includes a first portion and a second portion, the second portion includes a first end connected to the first portion and a second end exposed from a lateral surface of the encapsulant, and the first portion and the second portion are formed from a same conductive material.

In one or more embodiments, a method for manufacturing a semiconductor device package includes providing a substrate including electronic components disposed over a surface thereof; encapsulating the electronic components and a portion of the surface of the substrate to form an encapsulant; and removing a portion of the encapsulant to form a trench and a slit in the encapsulant, where a first end of the slit is in communication with the trench, the second end of the slit is exposed from a lateral surface of the encapsulant, and a width of the slit is less than a width of the trench. The method further includes disposing a conductive material in the trench and allowing the conductive material to enter the slit; and curing the conductive material.

### BRIEF DESCRIPTION OF THE DRAWINGS

Aspects of the present disclosure are best understood from the following detailed description when read with the accompanying figures. It is noted that various structures may not be drawn to scale, and the dimensions of the various structures may be arbitrarily increased or reduced for clarity of discussion.

FIG. 1 illustrates an example of a semiconductor device package in accordance with an embodiment of the present disclosure;

FIG. 1A is a cross-sectional view of the semiconductor device package of FIG. 1;

FIG. 1B is a cross-sectional view of the semiconductor device package of FIG. 1;

FIG. 2 illustrates an example of a semiconductor device package in accordance with an embodiment of the present disclosure;

FIG. 3 illustrates an example of a semiconductor device package in accordance with an embodiment of the present disclosure;

FIG. 4 illustrates an example of a semiconductor device package in accordance with an embodiment of the present disclosure;

FIG. 5 illustrates an example of a semiconductor device package in accordance with an embodiment of the present disclosure;

FIG. 6A illustrates an example of a semiconductor device package in accordance with an embodiment of the present disclosure;

FIG. 6B is a cross-sectional view of the semiconductor device package of FIG. 6A;

FIG. 7 illustrates an example of a semiconductor device package in accordance with an embodiment of the present disclosure;

FIG. 8 illustrates an example of a semiconductor device package in accordance with an embodiment of the present disclosure;

FIG. 9 illustrates an example of a semiconductor device package in accordance with an embodiment of the present disclosure;

FIG. 10A, FIG. 10B, FIG. 10C, FIG. 10D, FIG. 10E, FIG. 10F and FIG. 10G illustrate a method of manufacturing a semiconductor device package in accordance with an embodiment of the present disclosure; and

FIG. 11A, FIG. 11B, FIG. 11C and FIG. 11D illustrate a method for disposing a conductive material in accordance with an embodiment of the present disclosure.

### DETAILED DESCRIPTION

A semiconductor device package can include an encapsulant. A conductive compartment structure can be formed in the encapsulant to separate one or more electronic components in the semiconductor device package from other electronic components in the semiconductor device package, to reduce EMI transmitted or received. An example of a conductive compartment structure is a conductive material filled in a trench. The conductive material may have a relatively low viscosity. During manufacture, as the conductive material is applied within the trench, the conductive material may flow out of the trench due to its low viscosity, and may contact conductive pads or traces on the package substrate and thereby cause a short circuit. To avoid such flow out of the trench, the trench may be blocked (e.g., by encapsulant). Subsequent to applying the conductive material in the trench, it may be desirable to remove or trim the blockage of the trench. Dimensions of trimmed areas may be measured to verify suitability for subsequent operations. Cleaning may be desirable to facilitate subsequent operation (such as applying a conformal shielding on the encapsulant). The trimming, cleaning and measuring operations can increase costs of manufacturing the semiconductor device package.

The present disclosure provides many different embodiments, or examples, for implementing different features of the provided subject matter. Specific examples of components and arrangements are described below by way of example, and are not to be construed as limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of clarity and does not in itself dictate a relationship between the various embodiments and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such arrangement.

The following description is directed to a semiconductor device package. The semiconductor device package includes electronic components encapsulated by an encapsulant and shielded by a conductive compartment structure. The conductive compartment structure is in the encapsulant and between the electronic components. The conductive compartment structure includes a wider portion distal to a lateral surface of the encapsulant, and a narrow portion proximal to the lateral surface of the encapsulant. The following description is also directed to a method of manufacturing a semiconductor device package, as discussed below.

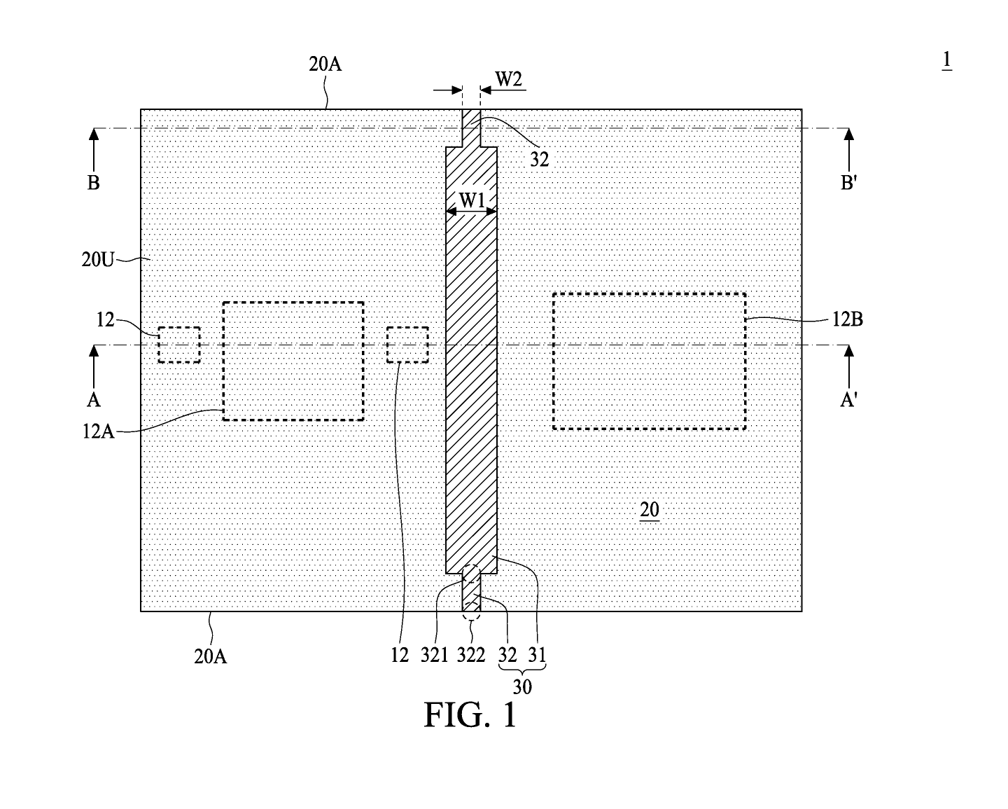

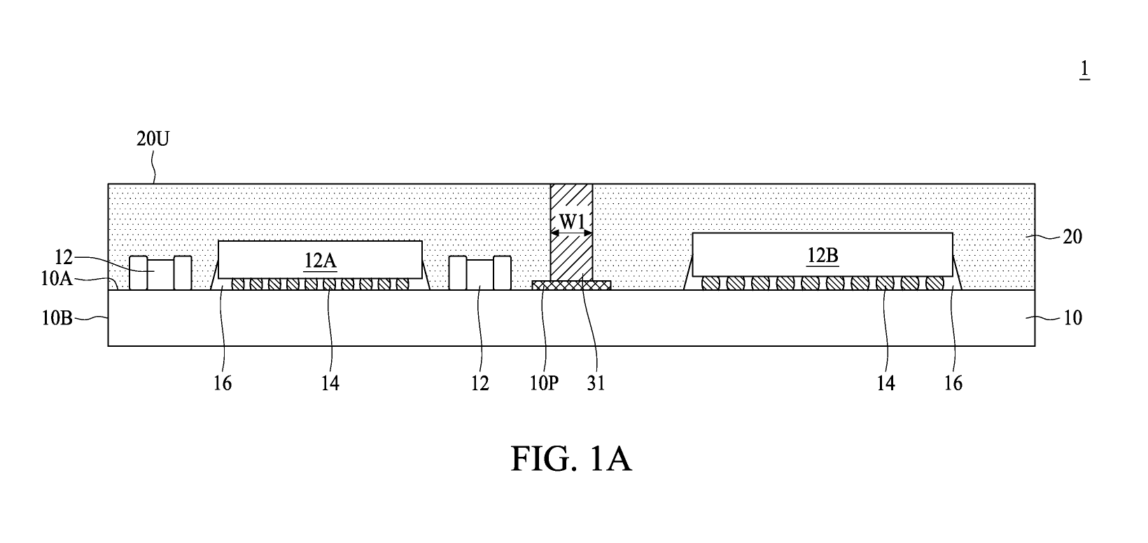

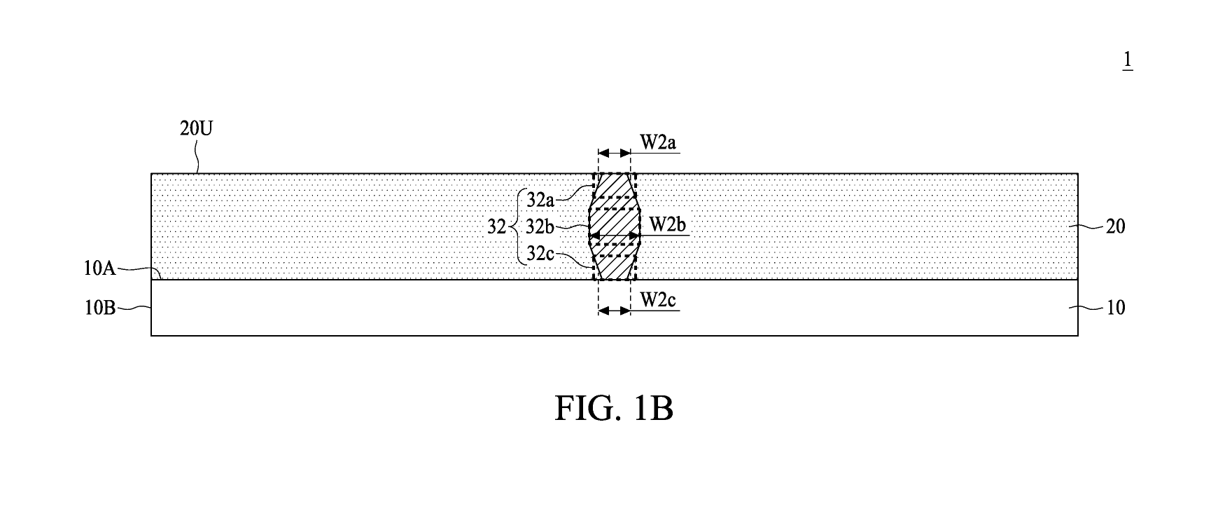

FIG. 1 is a top view illustration of an example of a semiconductor device package 1 in accordance with an embodiment of the present disclosure, FIG. 1A is a cross-sectional view of the semiconductor device package 1 along a line A-A′ in FIG. 1, and FIG. 1B is a cross-sectional view of the semiconductor device package 1 along a line B-B′ in FIG. 1. As shown in FIGS. 1, 1A and 1B, the semiconductor device package 1 includes a substrate 10, at least two electronic components 12 (e.g., electronic components 12A and 12B), an encapsulant 20 and a conductive compartment structure 30. The substrate 10 has an upper surface 10A and lateral surfaces 10B. In one or more embodiments, the substrate 10 is a circuit board, such as a printed circuit board (PCB) with circuit or conductive layer(s) integrated. In one or more embodiments, the substrate 10 may be a semiconductor substrate, an interposer, a package substrate, or other suitable substrate. In one or more embodiments, the upper surface 10A is an upper surface configured to receive the electronic components 12. The electronic components 12 are disposed over the upper surface 10A of the substrate 10, and electrically connected to circuit or conductive layer(s) of the substrate 10. In one or more embodiments, the electronic components 12 are mounted on bonding pads (not shown) arranged on, or exposed at, the upper surface 10A of the substrate 10 through conductors 14 such as, but not limited to, solder balls, solder pastes, pillars, or the like. In one or more embodiments, an underfill layer 16 is formed between the substrate 10 and the electronic components 12. The electronic components 12 may include active components or passive components, such as, for example, transistors, diodes, switches, inductors, capacitors, resistors, or various other types of electronic components.

The encapsulant 20 encapsulates the electronic components 12 (e.g., 12A and 12B). In one or more embodiments, the encapsulant 20 covers exposed surfaces (e.g., an upper surface and lateral surfaces) of the electronic components 12. The encapsulant serves to protect the electronic components from physical damage. The encapsulant 20 includes lateral surfaces 20A.

In one or more alternative embodiments, the underfill layer 16 is omitted, and the encapsulant 20 may include a molding underfill (MUF) incorporating a molding compound with an underfill layer.

The conductive compartment structure 30 is embedded in the encapsulant 20 and separates one or more of the electronic components 12 from others of the electronic components 12. In one or more embodiments, the electronic components 12 include highly electromagnetic (EM) emissive components such as RFICs, transceiver integrated circuits (ICs) or the like, or components sensitive to EMI, and thus one or more of the electronic components 12 are isolated from others of the electronic components 12 to reduce effects of EMI (e.g., crosstalk between devices).

By way of example, as illustrated in FIG. 1 and FIG. 1A, the electronic component 12A is disposed at one side of the conductive compartment structure 30, and the electronic component 12B is disposed at another side of the conductive compartment structure 30. In one or more embodiments, a portion of the conductive compartment structure 30 is exposed from an upper surface 20U of the encapsulant 20. The conductive compartment structure 30 is configured to reduce EMI between the two electronic components 12A, 12B disposed on opposite sides of the conductive compartment structure 30. For example, a height and a width of the conductive compartment structure 30 are designed considering an expected frequency range, directivity and amplitude of EM emissions from one of the electronic components 12A or 12B. In one or more embodiments, the conductive compartment structure 30 penetrates the encapsulant 20 in a depth direction, and is in contact with a portion of the upper surface 10A of the substrate 10, or in contact with an overlying structure over the upper surface 10A of the substrate 10.

In one or more embodiments, the semiconductor device package 1 includes a ground pad 10P disposed on the upper surface 10A of the substrate 10, and the conductive compartment structure 30 is electrically connected to the ground pad 10P. In one or more embodiments, the height of the conductive compartment structure 30 ranges from about 400 micrometers (μm) to about 1200 μm. In one or more embodiments, the ground pad 10P is configured to be grounded or supplied with a reference potential.

The conductive compartment structure 30 includes a first portion 31 not exposed at the lateral surface 20A of the encapsulant 20, and a second portion 32 with one end 321 connected to the first portion 31 and the other end 322 exposed from the lateral surface 20A of the encapsulant 20. In one or more embodiments, two second portions 32 are connected to two opposite ends of the first portion 31, respectively, as illustrated in FIG. 1. In one or more embodiments, the end 322 of the second portion 32 is substantially coplanar with the lateral surface 20A of the encapsulant 20.

In one or more embodiments, the first portion 31 and the second portion 32 are formed of a same conductive material, such as, for example, a conductive glue. By way of example, the conductive glue can include epoxy silver glue or the like. In one or more embodiments, the first portion 31 and the second portion 32 are monolithically formed, meaning that the first portion 31 and the second portion 32 together are a one-piece structure.

A width W2 of the second portion 32 is less than a width W1 of the first portion 31. By way of example, the width W1 of the first portion 31 ranges from approximately 180 μm to approximately 700 μm, and the width W2 of the second portion 32 ranges from approximately 25 μm to approximately 150 μm. In one or more embodiments, a ratio of the width W1 of the first portion 31 to the width W2 of the second portion 32 ranges from approximately 1.2 to approximately 28, such as approximately 1.2 to approximately 5, approximately 1.2 to approximately 10, approximately 5 to approximately 20, or other range subsumed within any of the above.

In one or more embodiments, the first portion 31 of the conductive compartment structure 30 has a rectangular cross-sectional shape, such as illustrated by way of example in FIG. 1A.

In one or more embodiments, such as illustrated by way of example in FIG. 1B, the second portion 32 of the conductive compartment structure 30 includes a first part 32a, a second part 32b and a third part 32c along the depth direction. The first part 32a is proximal to the upper surface 20U of the encapsulant 20, the third part 32c is proximal to the upper surface 10A of the substrate 10, and the second part 32b is between the first part 32a and the third part 32c. In one or more embodiments, the second part 32b has a largest width, that is, a width W2b of the second part 32b is greater than a width W2a of the first part 32a and a width W2c of the third part 32c. The widths W2a, W2b and W2c are all within a range of the width W2 of the second portion 32, which is less than the width W1 of the first portion 31. In one or more embodiments, the width W2a ranges from approximately 80 μm to approximately 150 μm; the width W2b ranges from approximately 80 μm to approximately 150 μm; and the width W2c ranges from approximately 25 μm to approximately 80 μm.

In one or more embodiments, the first portion 31 of the conductive compartment structure 30 has a rectangular shape from a top view, which forms a shield to divide the semiconductor device package 1 into two compartments (e.g., as illustrated in FIG. 1), thereby reducing EMI between electronic components 12 disposed in the chambers on opposite sides of the conductive compartment structure 30. It is to be understood that in other embodiments, the conductive compartment structure 30 may have other shapes, and may divide the semiconductor device package 1 into more than two compartments to provide additional shielding.

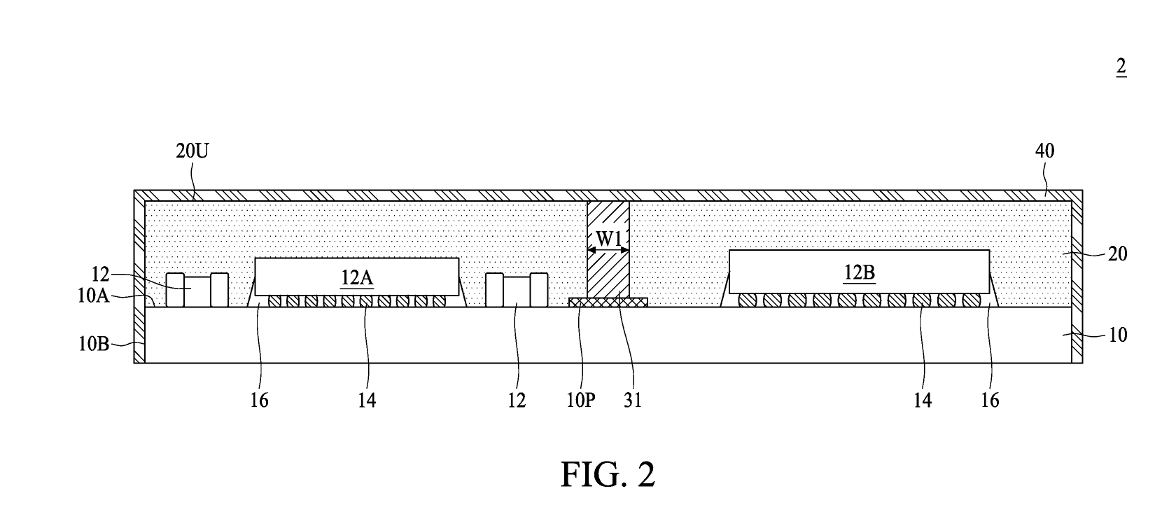

FIG. 2 is a cross-sectional illustration of an example of a semiconductor device package 2 in accordance with an embodiment of the present disclosure. The semiconductor device package 2 is similar to the semiconductor device package 1 illustrated in FIG. 1A, and same-numbered features are not discussed again. As shown in FIG. 2, the semiconductor device package 2 further includes a conductive shield 40. In one or more embodiments, the conductive shield 40 is disposed on the encapsulant 20, and is in contact with the conductive compartment structure 30. In one or more embodiments, the conductive shield 40 covers the upper surface 20U of the encapsulant 20. In one or more embodiments, the conductive shield 40 covers one or more lateral surfaces of the encapsulant 20. In one or more embodiments, the conductive shield 40 further covers one or more lateral surfaces 10B of the substrate 10. In one or more embodiments, the conductive shield 40 further covers at least a portion of the exposed upper surface 10A of the substrate 10. The conductive shield 40 is configured to further reduce EMI between the electronic components 12 (inside the semiconductor device package 2), as well as reducing EMI between the electronic components 12 and external electronic components (outside the semiconductor device package 2). In one or more embodiments, the conductive shield 40 is a conformal shield, and includes one or more metals or other conductive materials.

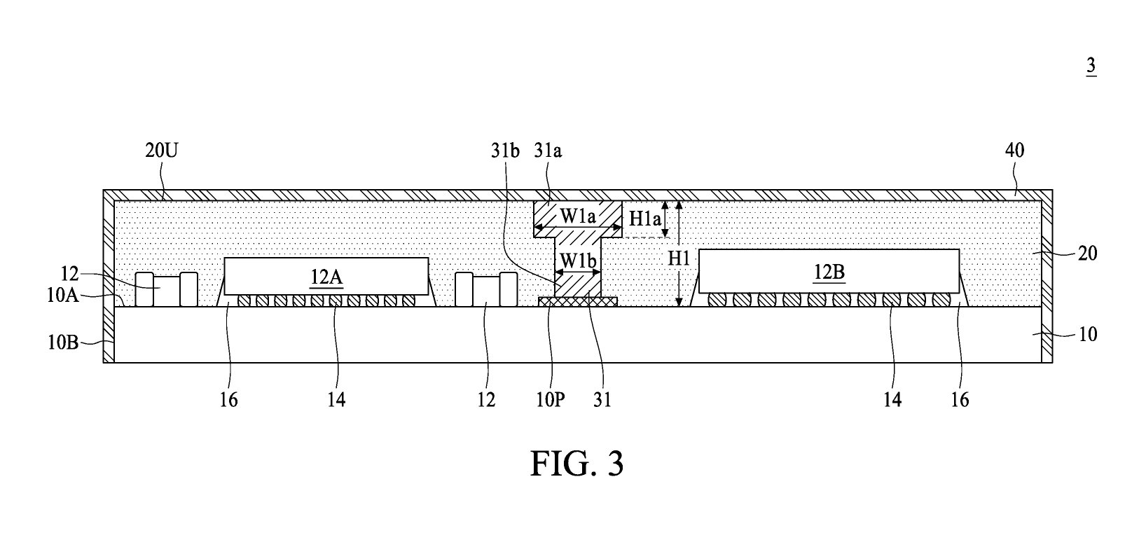

FIG. 3 is a cross-sectional illustration of an example of a semiconductor device package 3 in accordance with an embodiment of the present disclosure. The semiconductor device package 3 is similar to the semiconductor device package 2 illustrated in FIG. 2, and same-numbered features are not discussed again. As shown in FIG. 3, the first portion 31 of the conductive compartment structure 30 includes an upper part 31a and a lower part 31b located between the upper part 31a and the upper surface 10A of the substrate 10. A portion of the upper part 31a is exposed form the upper surface 20U of the encapsulant 20. The upper part 31a and the lower part 31b are both rectangular in cross-sectional shape. A width W1a of the upper part 31a is greater than a width W1b of the lower part 31b. In one or more embodiments, a height H1 of the conductive compartment structure 30 ranges from approximately 400 μm to approximately 1200 μm. In one or more embodiments, a height H1a of the upper part 31a ranges from approximately 60 μm to approximately 100 μm.

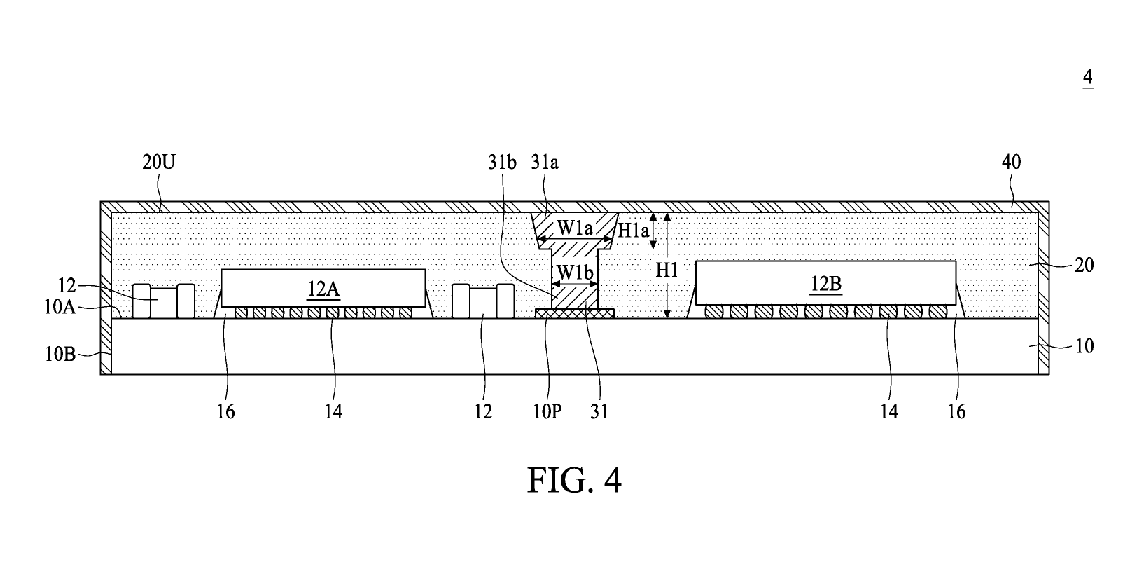

FIG. 4 is a cross-sectional illustration of an example of a semiconductor device package 4 in accordance with an embodiment of the present disclosure. The semiconductor device package 4 is similar to the semiconductor device package 3 illustrated in FIG. 3, and same-numbered features are not discussed again. As shown in FIG. 4, the upper part 31a has an inverted trapezoidal cross-sectional shape and the lower part 31b has a rectangular cross-sectional shape. The width W1a along the entirety of the upper part 31a is greater than the width W1b of the lower part 31b. In one or more embodiments, the height H1 of the conductive compartment structure 30 ranges from approximately 400 micrometers to approximately 1200 micrometers. In one or more embodiments, the height H1a of the upper part 31a ranges from approximately 60 micrometers to approximately 100 micrometers.

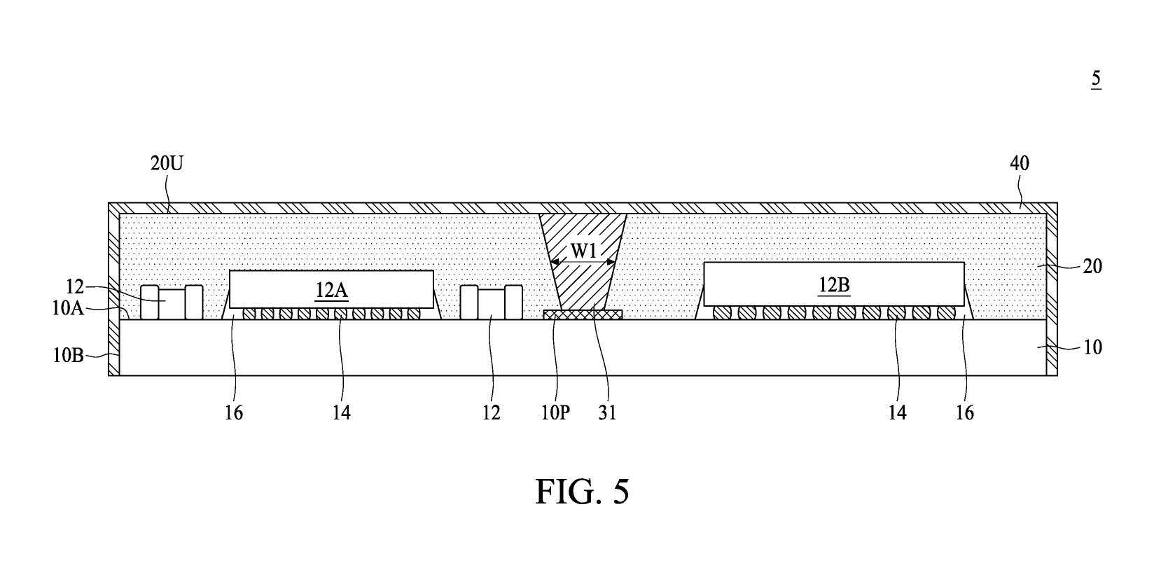

FIG. 5 is a cross-sectional illustration of an example of a semiconductor device package 5 in accordance with an embodiment of the present disclosure. The semiconductor device package 5 is similar to the semiconductor device package 2 illustrated in FIG. 2, and same-numbered features are not discussed again. As shown in FIG. 5, the first portion 31 of the conductive compartment structure 30 has an inverted trapezoidal cross-sectional shape. The width W1 of the first portion 31 decreases from the upper surface 20U of the encapsulant 20 to the upper surface 10A of the substrate 10.

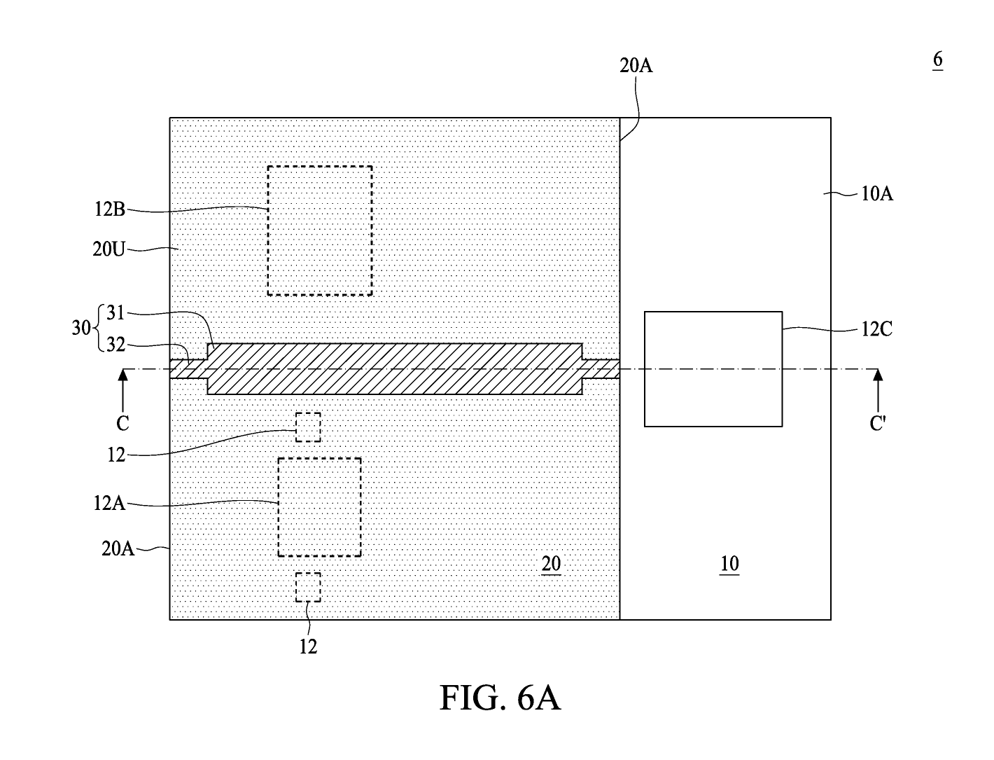

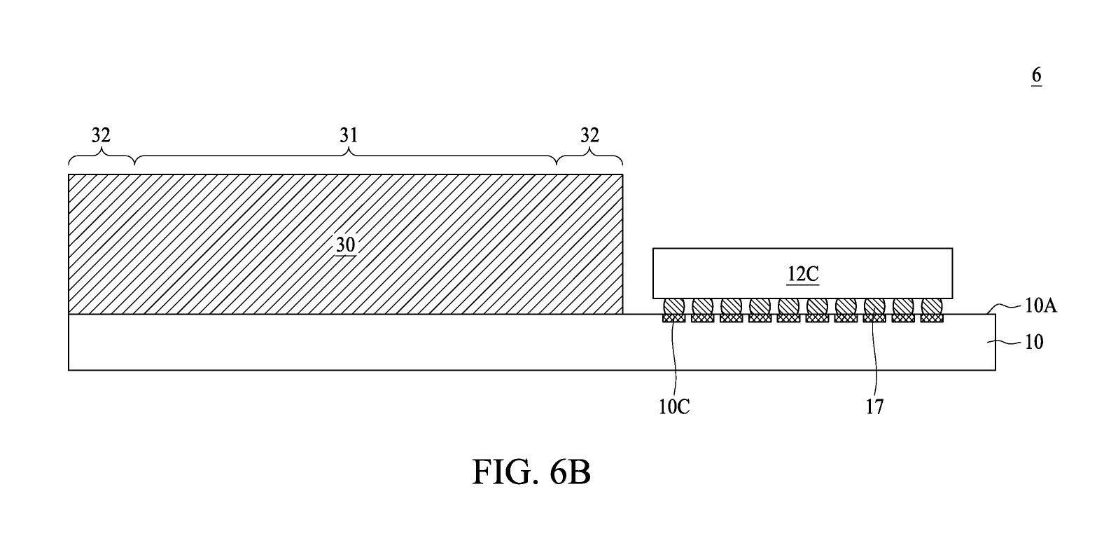

FIG. 6A is a top view illustration of an example of a semiconductor device package 6 in accordance with an embodiment of the present disclosure, and FIG. 6B is a cross-sectional view of the semiconductor device package 6 along a line C-C′ in FIG. 6A. As shown in FIGS. 6A and 6B, an encapsulant 20 encapsulates a portion of an upper surface 10A of a substrate 10, and exposes another portion of the upper surface 10A of the substrate 10. The semiconductor device package 6 further includes conductive elements 10C (FIG. 6B) disposed on, or embedded in, the upper surface 10A of the substrate 10, and exposed from the encapsulant 20. An electronic component 12C of the electronic components 12 is disposed over the upper surface 10A of the substrate 10, electrically connected to one or more of the conductive elements 10C and adjacent to the encapsulant 20. In one or more embodiments, the electronic component 12C is electrically connected to the one or more conductive elements 10C through respective one or more conductors 17, such as solder balls, solder pastes or the like.

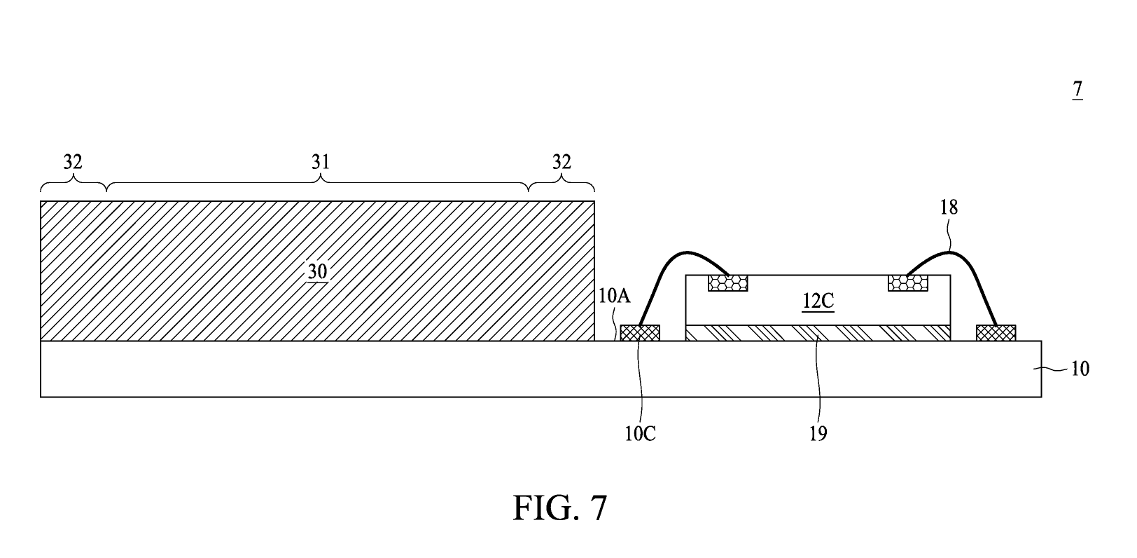

FIG. 7 is a cross-sectional illustration of an example of a semiconductor device package 7 in accordance with an embodiment of the present disclosure. The semiconductor device package 7 is similar to the semiconductor device package 6 illustrated in FIG. 6B, and same-numbered features are not discussed again. As shown in FIG. 7, the second electronic component 12C is attached over the upper surface 10A of the substrate 10 with an adhesion layer 19 such as a die attach film (DAF), and is electrically connected to one or more conductive elements 10C disposed on or embed in the substrate 10 through bonding wires 18.

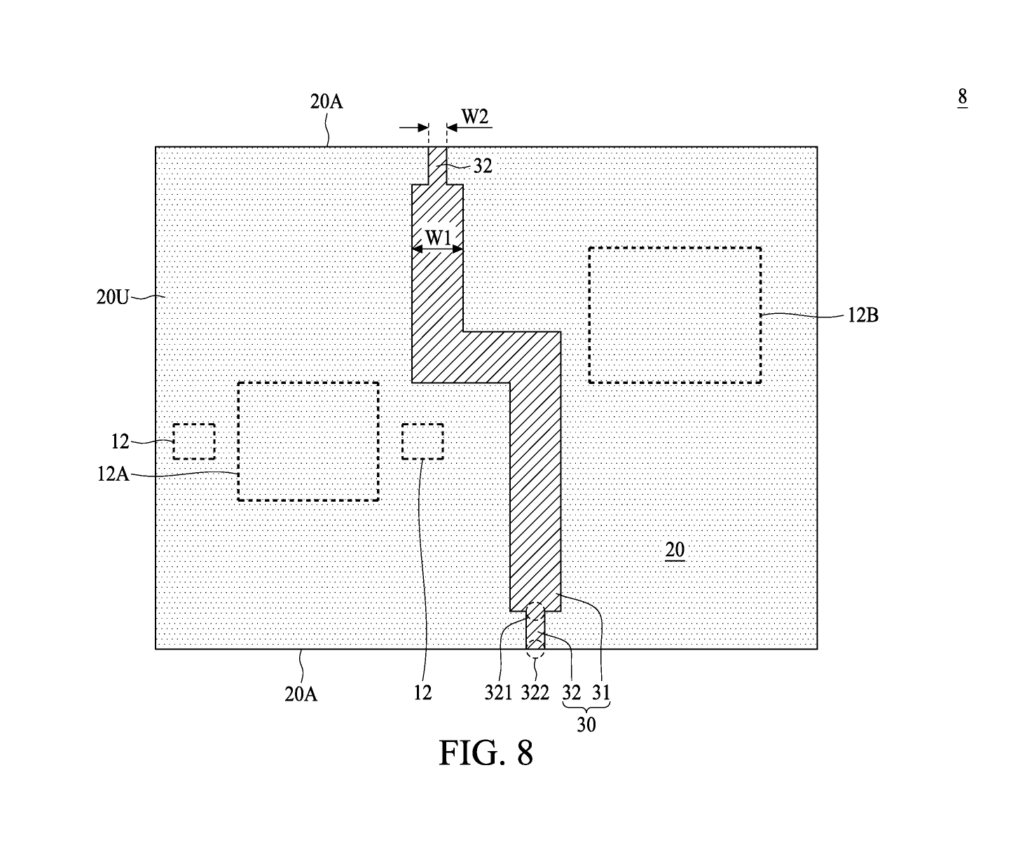

FIG. 8 is a top view illustration of an example of a semiconductor device package 8 in accordance with an embodiment of the present disclosure. The semiconductor device package 8 is similar to the semiconductor device package 1 illustrated in FIG. 1, and same-numbered features are not discussed again. As shown in FIG. 8, instead of a linear structure along its length from a top view as illustrated in FIG. 1, the first portion 31 of the conductive compartment structure 30 in FIG. 8 is non-linear along its length from the top view (e.g., has a zigzag shape).

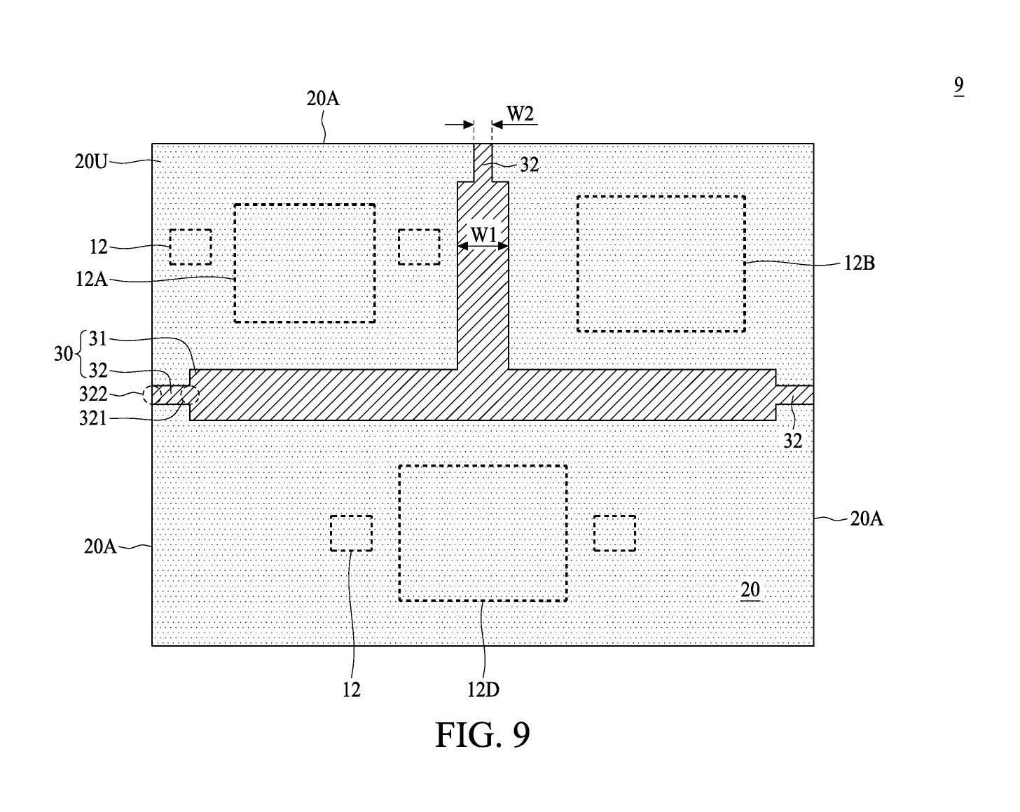

FIG. 9 is a top view illustration of an example of a semiconductor device package 9 in accordance with an embodiment of the present disclosure. The semiconductor device package 9 is similar to the semiconductor device package 1 illustrated in FIG. 1, and same-numbered features are not discussed again. As shown in FIG. 9, instead of a linear structure along its length from a top view as illustrated in FIG. 1, the first portion 31 of the conductive compartment structure 30 in FIG. 9 includes intersecting linear portions from the top view (e.g., has a T-shape), and divides the semiconductor device package 9 into three compartments with electronic components 12 in each compartment (e.g., 12A, 12B, and 12D each in a different compartment with optional other electrical components 12). In one or more embodiments, three second portions 32 are connected to three ends of the first portion 31, respectively.

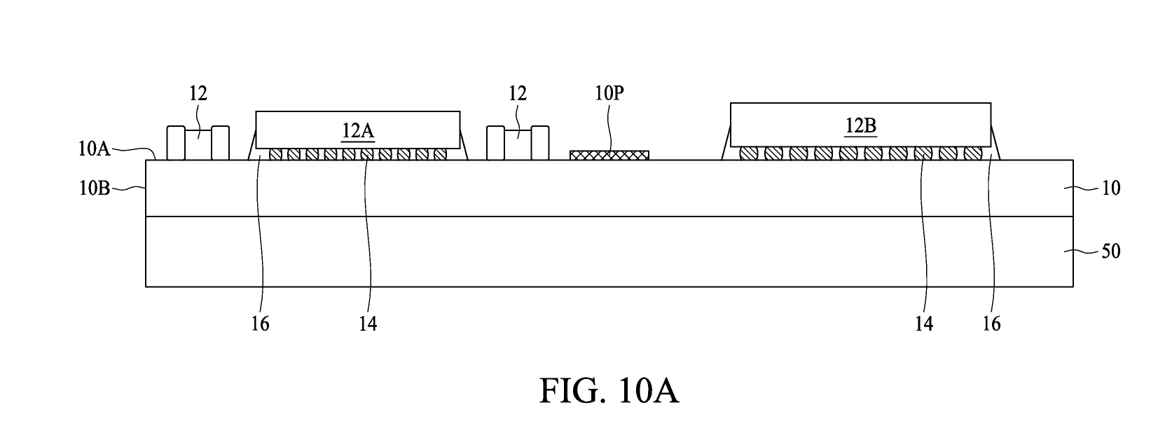

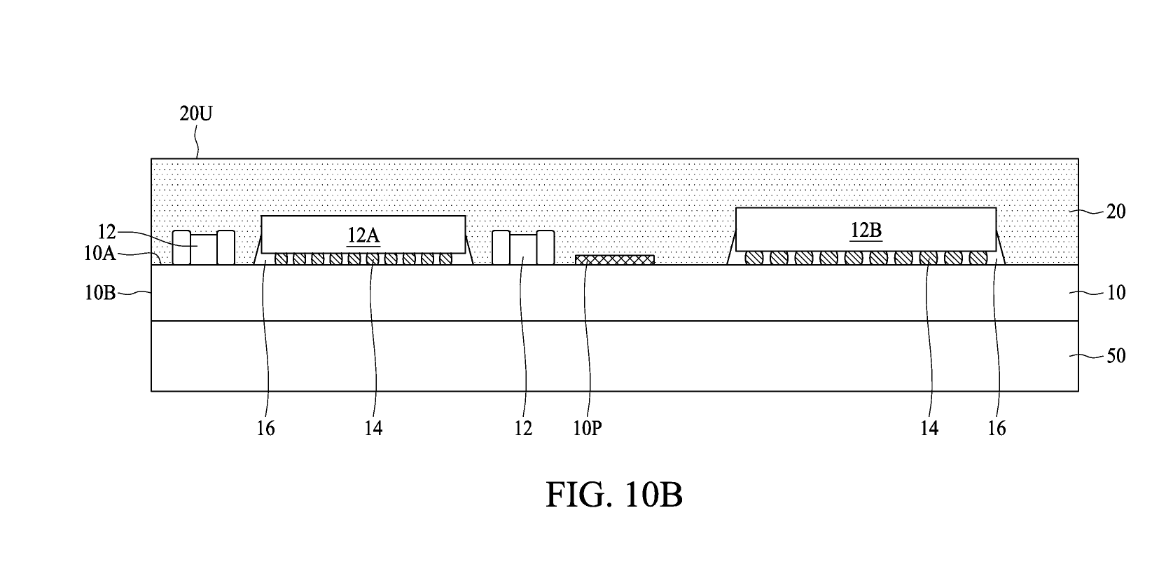

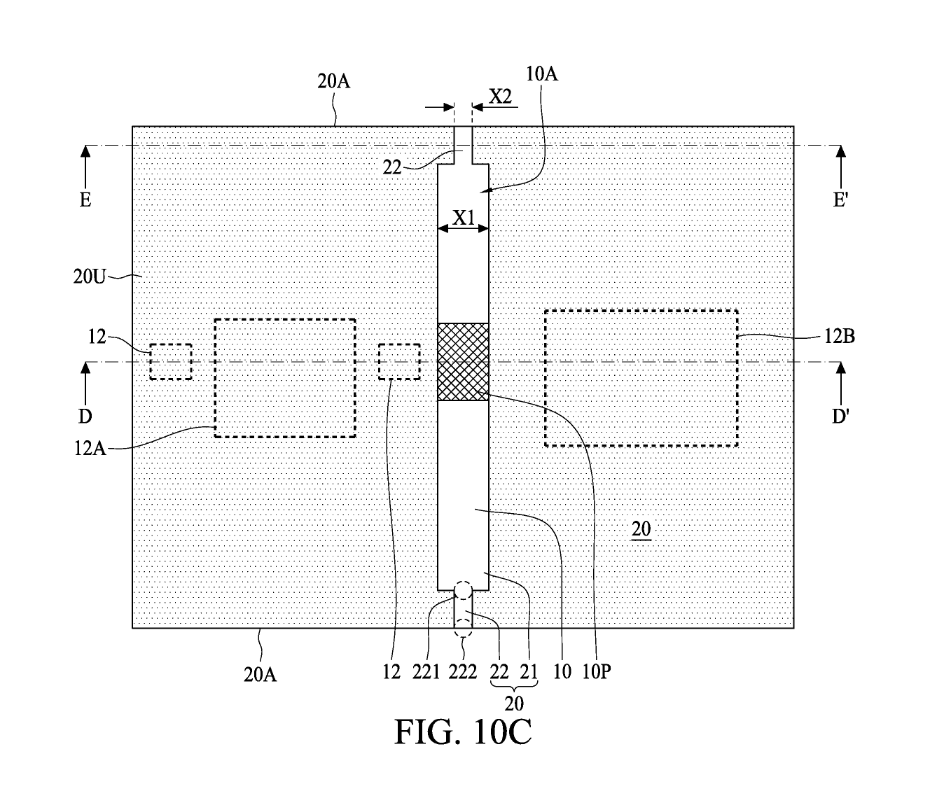

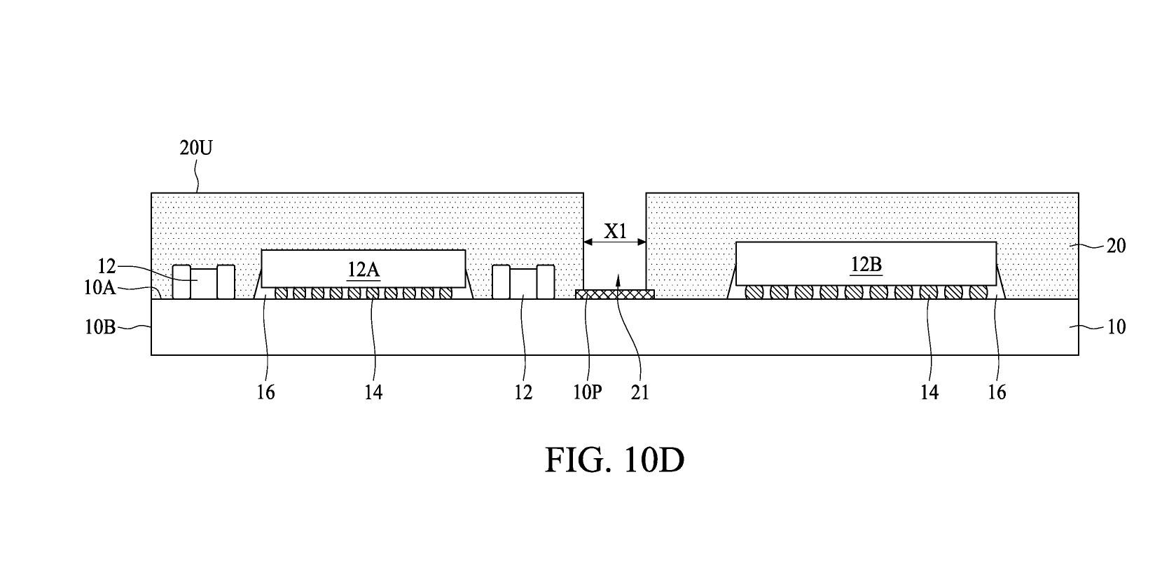

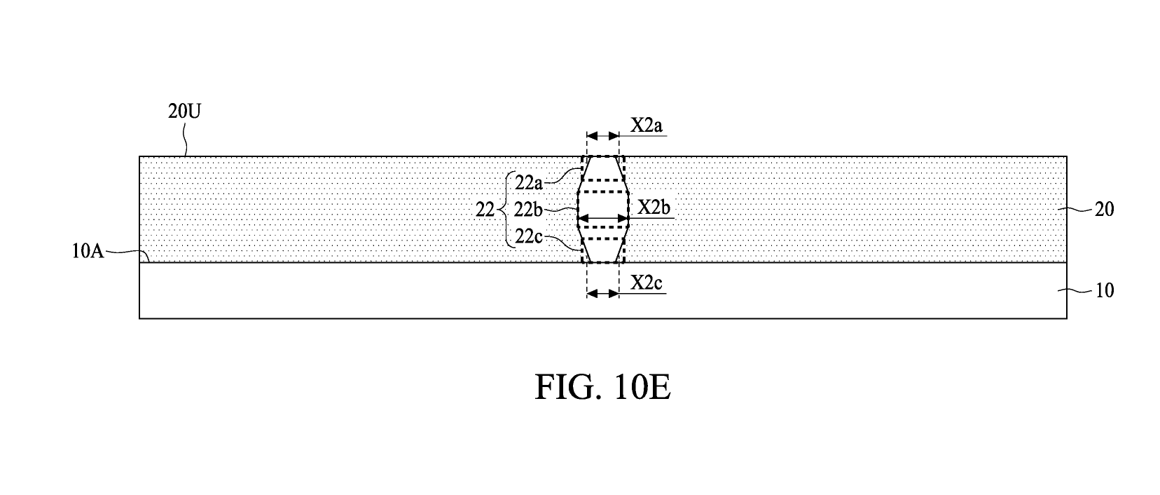

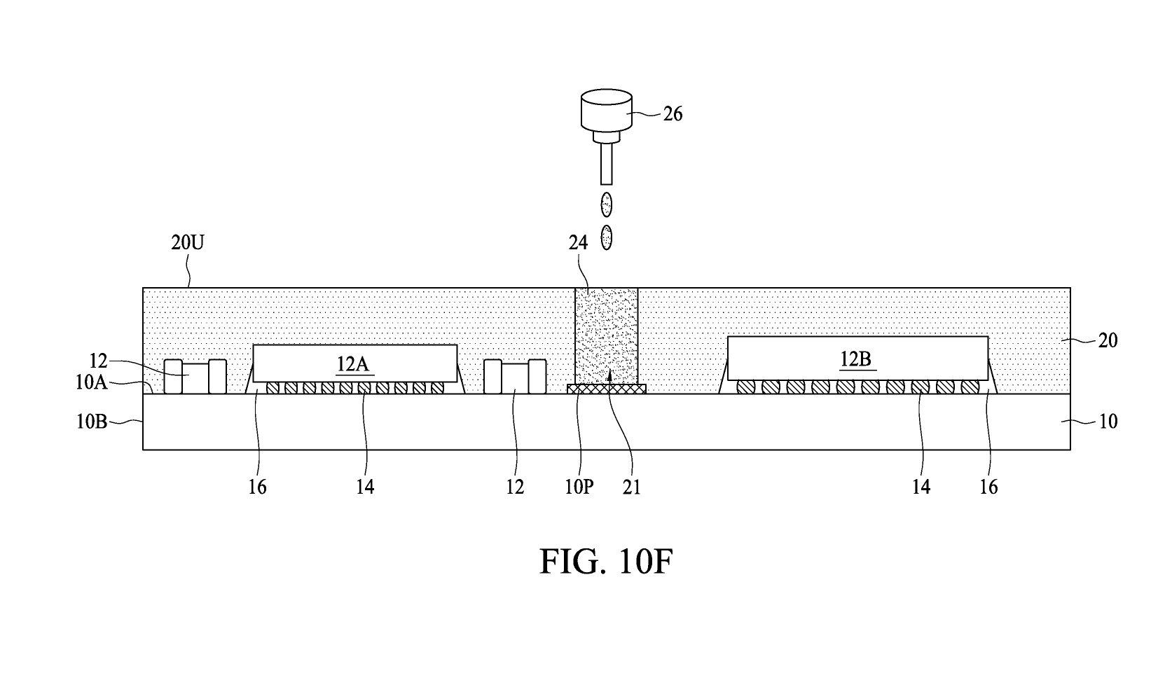

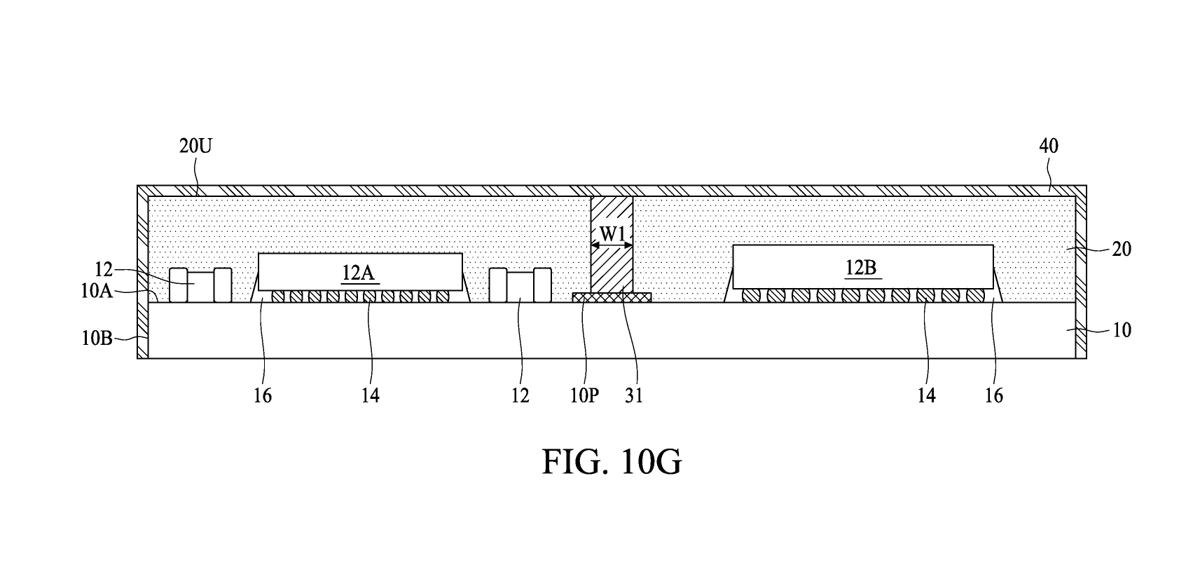

FIGS. 10A-10G illustrate an example of a manufacturing method for fabricating semiconductor device packages according to embodiments of the present disclosure.

Referring to FIG. 10A, a substrate 10 with several electronic components 12 disposed thereon is provided (including, e.g., electronic components 12A, 12B). In one or more embodiments, the substrate 10 is placed and affixed on a carrier 50. A ground pad 10P is disposed on or exposed from the upper surface 10A of the substrate 10. The electronic components 12 are mounted on the upper surface 10A of the substrate 10 through a suitable surface mounting technique (SMT). For example, one or more electronic components 12 are mounted on bonding pads (not shown) on, or exposed at, the upper surface 10A of the substrate 10 through conductors 14 such as solder balls, solder pastes or the like. In one or more embodiments, an underfill layer 16 is formed between the substrate 10 and the electronic components 12. In one or more embodiments, a pre-baking is performed at about 125° C. for about 4 hours prior to forming the underfill layer 16. The underfill layer 16 is then disposed and baked at, for example, about 165° C. for about 2 hours. It is to be understood that other pre-baking and baking time and temperature profiles are also within the scope of the present disclosure.

Referring to FIG. 10B, the electronic components 12 and the substrate 10 are encapsulated with an encapsulant 20. The encapsulant 20 has lateral surfaces 20A and an upper surface 20U. In one or more embodiments, the encapsulant 20 is formed by a molding process, and thermally cured at about 175° C. for about 4 hours. It is to be understood that other curing time and temperature profiles are also within the scope of the present disclosure. The substrate 10 may be released from the carrier 50.

Referring to FIGS. 10C, 10D and 10E, FIG. 10C is a top view, FIG. 10D is a cross-sectional view along a line D-D′ in FIG. 10C, and FIG. 10E is a cross-sectional view along a line E-E′ in FIG. 10C.

In FIGS. 10C, 10D, and 10E, a portion of the encapsulant 20 is removed to form a trench 21 and a slit 22 in the encapsulant 20 and to expose the ground pad 10P and a portion of the upper surface 10A of the substrate 10. In one or more embodiments, the ground pad 10P may extend from one lateral side to another lateral side of the substrate 10. In one or more embodiments, the encapsulant 20 is partially removed by a laser cutting technique. The trench 21 and the slit 22 penetrate through the encapsulant 20 to the ground pad 10P and the upper surface 10A of the substrate 10. An end 222 of the slit 22 is exposed from one lateral surface 20A, and the other end 221 of the slit 22 is in communication with the trench 21. A width X2 of the slit 22 is less than a width X1 of the trench 21. In one or more embodiments, a ratio of the width X1 of the trench 21 to the width X2 of the slit 22 ranges from approximately 1.2 to approximately 28. In one or more exemplary embodiments, the width X1 of the trench 21 ranges from approximately 180 μm to approximately 700 μm, and the width X2 of the slit 22 ranges from approximately 25 μm to approximately 150 μm.

As shown in FIG. 10E, when the slit 22 is formed by laser cutting, the slit 22 may have different widths at different depths. In one or more embodiments, the slit 22 includes a first region 22a, a second region 22b and a third region 22c. The first region 22a is proximal to the upper surface 20U of the encapsulant 20, the third region 22c is proximal to the substrate 10, the second region 22b is between the first region 22a and the third region 22c, and a width X2b of the second region 22b is greater than a width X2a of the first region 22a and a width X2c of the third region 22c. The widths X2a, X2b and X2c of the slit 21 are all within the range of the width X2, which is less than the width X1 of the trench 21. In one or more embodiments, the width X2a ranges from approximately 80 μm to approximately 150 μm; the width X2b ranges from approximately 80 μm to approximately 150 μm; and the width X2c ranges from approximately 25 μm to approximately 80 μm.

Referring to FIG. 10F, a conductive material 24 such as a conductive glue is disposed in the trench 21 and the slit 22. In one or more embodiments, the conductive material 24 is dispensed in the trench 21 by a nozzle 26 or the like, and the conductive material 24 then flows into the slit 22. In one or more embodiments, screen printing, spray coating, or 3D spray coating may be used to fill the conductive material 24 into the trench 21. In one or more embodiments, a viscosity of the conductive material 24 ranges from approximately 2500 centipoise (cp) to approximately 8000 cp at about 25° C. During dispensing of the conductive material 24, the temperature is maintained at a relatively high temperature to maintain fluidity of the conductive material 24. In one or more embodiments, the conductive material 24 is heated to about 75° C. by, for example, a heating board installed under the substrate 10. In an embodiment, the conductive material 24 is an epoxy silver glue containing silver, epoxy resin, solvent and other additives. A particle size of the conductive material 24 is less than the width X2 of the slit 21 such that the conductive material 24 is able to flow into the slit 21. In one or more embodiments, the particle size of the conductive material 24 such as the particle size of epoxy resin ranges from approximately 0.5 μm to approximately 25 μm.

The conductive material 24 is then cured to form a conductive compartment structure 30. In one or more embodiments, the conductive material 24 is cured in multiple stages, which includes a first heating stage, a second heating stage and a thermostatic stage. In some embodiments, the first heating stage heats the conductive material 24 from about 25° C. to about 50° C. in about 10 minutes; the second heating stage heats the conductive material 24 from about 50° C. to about 175° C. in about 30 minutes; and the temperature is maintained at about 175° C. for about 60 minutes.

Referring to FIG. 10G, a conductive shield 40 is formed on the encapsulant 20 and the conductive compartment structure 30. In one or more embodiments, the conductive shield 40 is a conformal shield formed by deposition or other suitable processes. In one or more embodiments, the conductive shield 40 is formed of a metal.

In one or more alternative embodiments, conductive elements (e.g., conductive elements 10C) and electronic components (e.g., electronic component 12C) are not encapsulated by the encapsulant 20, and the second electronic component 12C is away from the conductive compartment structure 30 (e.g., as shown in FIGS. 6A-6B or FIG. 7).

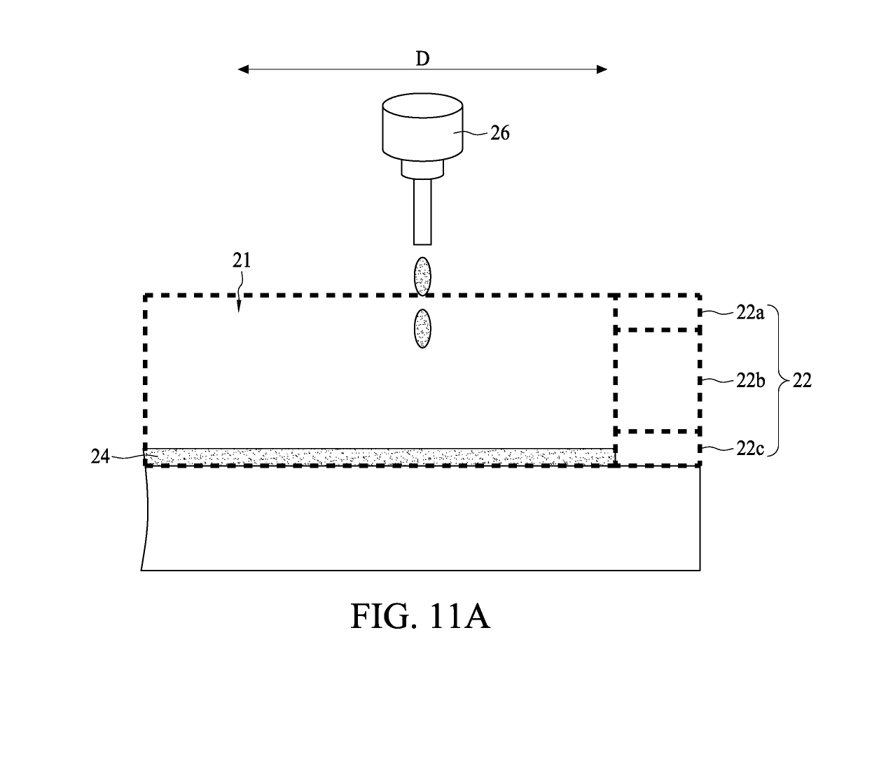

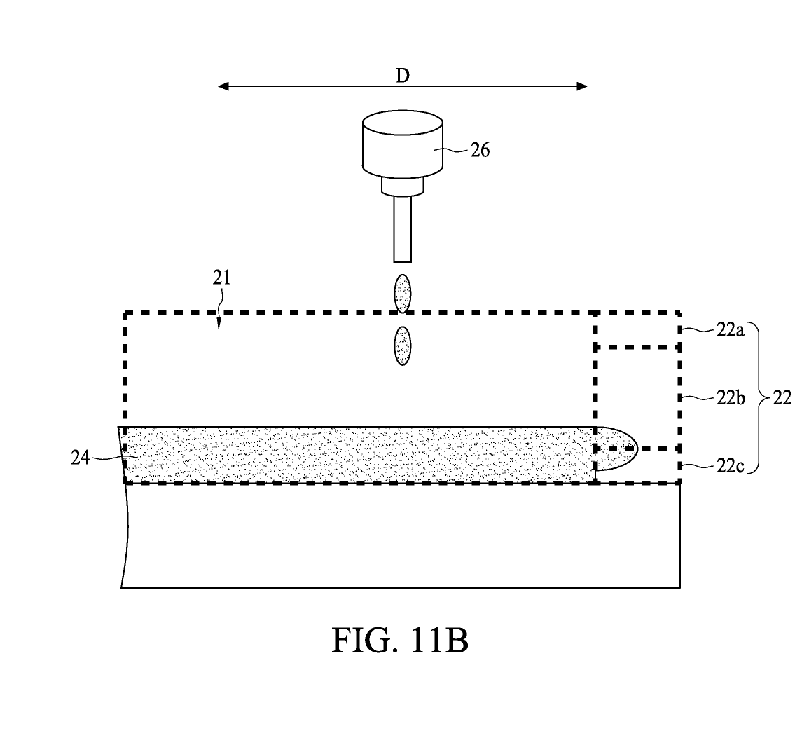

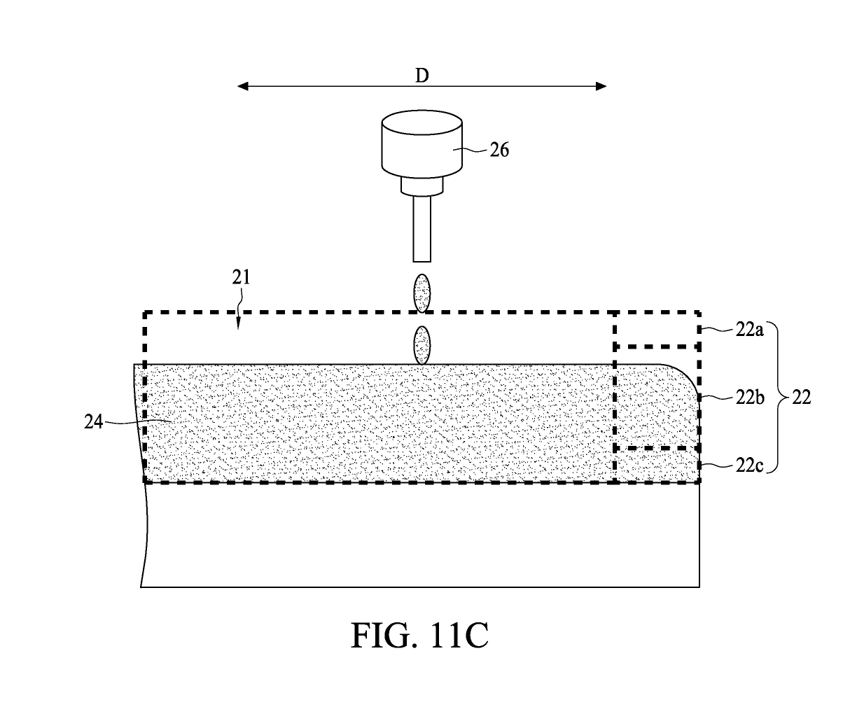

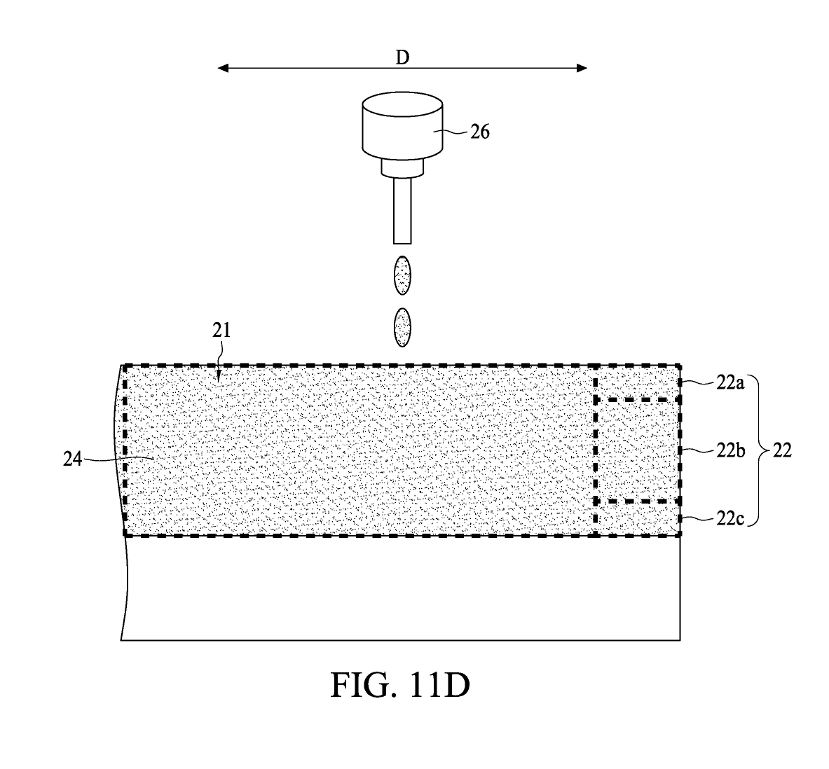

FIGS. 11A-11D illustrate an example of a method for disposing a conductive material at one of various stages in accordance with an embodiment of the present disclosure. The example of FIGS. 11A-11D is described with respect to the numbering illustrate in FIG. 10F for convenience.

Referring to FIG. 11A, the conductive material 24 is dispensed in the trench 21 by a nozzle 26 in a back and forth motion along a direction D. Because the third region 22c of slit 22 has the smallest width, the conductive material 24 is not prone to flow from the trench 21 into the third region 22c of the slit 22.

Referring to FIG. 11B, as the amount of the conductive material 24 increases until a level of the conductive material 24 reaches the second region 22b of the slit 22, the conductive material 24 begins to flow into the second region 22b, which has a width greater than that of the third region 22c.

Referring to FIG. 11C, as the conductive material 24 continues to be dispensed in the trench 21, more conductive material 24 in the trench 21 will flow into the second region 22b, and the conductive material 24 will then flow downward into the third region 22c from the second region 22b.

Referring to FIG. 11D, as additional conductive material 24 is dispensed in the trench 21, the trench 21 and the slit 22 will be filled with conductive material 24. It is noted that the width of the slit 21 and characteristics of the conductive material 24 such as its viscosity are configured to prevent the conductive material 24 from flowing out of the slit 22 due to surface tension. As such, the conductive material 24 is able to provide EMI isolation, and is kept away from other structures such as the conductive element 10C and the electronic component 12C as shown in FIGS. 6A-6B or FIG. 7.

The semiconductor device package of the present disclosure includes a conductive compartment structure in an encapsulant that separates electronic components from each other, thereby providing an EMI shielding effect. The conductive compartment structure includes a wider portion distal to a lateral surface of the encapsulant, and a narrow portion proximal to the lateral surface of the encapsulant. The unequal design facilitates fabrication, reduces costs, and enhances an EMI shielding effect of the conductive compartment structure.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A semiconductor device package, comprising:
a substrate;
a plurality of electronic components disposed over a surface of the substrate;
an encapsulant encapsulating the electronic components; and
a conductive compartment structure separating at least one first electronic component of the plurality of electronic components from at least one second electronic component of the plurality of electronic components, wherein the conductive compartment structure includes a first portion and a second portion, the second portion includes a first end connected to the first portion and a second end exposed from a lateral surface of the encapsulant, and a width of the second portion is less than a width of the first portion, wherein the width of the first portion and the width of the second portion are measured along a direction in parallel to the lateral surface of the encapsulant.

2. The semiconductor device package according to claim 1, wherein the second portion of the conductive compartment structure includes a first part, a second part and a third part, the first part is proximal to an upper surface of the encapsulant, the third part is proximal to the surface of the substrate, the second part is between the first part and the third part, and a width of the second part is greater than a width of the first part and a width of the third part.

3. The semiconductor device package according to claim 1, wherein a ratio of the width of the first portion to the width of the second portion ranges from approximately 1.2 to approximately 28.

4. The semiconductor device package according to claim 3, wherein the width of the second portion ranges from approximately 25 micrometers to approximately 150 micrometers, and the width of the first portion ranges from approximately 180 micrometers to approximately 700 micrometers.

5. The semiconductor device package according to claim 1, wherein the lateral surface of the encapsulant is substantially coplanar with the second end of the second portion of the conductive compartment structure.

6. The semiconductor device package according to claim 1, further comprising conductive elements disposed at the surface of the substrate, wherein a third electronic component of the plurality of electronic components is disposed over the surface of the substrate and is electrically connected to at least one of the conductive elements.

7. The semiconductor device package according to claim 1, wherein the first portion comprises an upper part and a lower part located between the upper part and the surface of the substrate, a portion of the upper part is exposed from an upper surface of the encapsulant, and a width of the upper part is greater than a width of the lower part of the first portion.

8. The semiconductor device package according to claim 1, further comprising a ground pad disposed at the surface of the substrate, wherein the conductive compartment structure is electrically connected to the ground pad.

9. The semiconductor device package according to claim 1, further comprising a conductive shield disposed on the encapsulant and contacting the conductive compartment structure.

10. A semiconductor device package, comprising:
a substrate;
a plurality of electronic components disposed over a surface of the substrate;
an encapsulant covering at least a subset of the plurality of electronic components; and
a conductive compartment structure separating a first electronic component of the subset of the electronic components covered by the encapsulant from a second electronic component of the plurality of electronic components, wherein the conductive compartment structure includes a first portion and a second portion, the second portion comprises a first end connected to the first portion and a second end exposed from a lateral surface of the encapsulant, and the first portion and the second portion are formed from a same conductive material.

11. The semiconductor device package according to claim 10, wherein the second portion of the conductive compartment structure includes a first part, a second part and a third part arranged in a depth direction, the first part is proximal to an upper surface of the encapsulant, the third part is proximal to the surface of the substrate, the second part is between the first part and the third part, and a width of the second part is greater than a width of the first part and a width of the third part.

12. The semiconductor device package according to claim 10, wherein the lateral surface of the encapsulant is substantially coplanar with the second end of the second portion of the conductive compartment structure.

13. The semiconductor device package according to claim 10, further comprising conductive elements disposed on the surface of the substrate, wherein a third electronic component of the plurality of electronic components is electrically connected to at least one of the conductive elements.

14. The semiconductor device package according to claim 10, wherein the first portion comprises an upper part and a lower part located between the upper part and the surface of the substrate, a portion of the upper part is exposed from an upper surface of the encapsulant, and a width of the upper part is greater than a width of the lower part of the first portion.

15. The semiconductor device package according to claim 10, further comprising a ground pad disposed at the surface of the substrate, wherein the conductive compartment structure is electrically connected to the ground pad.

16. The semiconductor device package according to claim 10, further comprising a conductive shield covering the encapsulant and contacting the conductive compartment structure.

17-20. (canceled)

21. A semiconductor device package, comprising:
a substrate;
a first electronic component and a second electronic component disposed over a surface of the substrate;
an encapsulant encapsulating the first electronic component and the second electronic component; and
a conductive compartment structure separating the first electronic component from the second electronic component, wherein the conductive compartment structure includes a portion having an end exposed from a lateral surface of the encapsulant, the portion of the conductive compartment structure includes a first part, a second part and a third part, the first part is proximal to an upper surface of the encapsulant, the third part is proximal to the surface of the substrate, the second part is between the first part and the third part, a width of the second part is greater than a width of the first part, and the width of the second part is greater than a width of the third part, wherein the width of the first part, the width of the second part and the width of the third part are measured along a direction in parallel to the upper surface of the encapsulant.

22. The semiconductor device package according to claim 21, further comprising:
a conductive element disposed at the surface of the substrate; and
a third electronic component disposed over the surface of the substrate and electrically connected to the conductive element.

23. The semiconductor device package according to claim 21, further comprising a ground pad disposed at the surface of the substrate, wherein the conductive compartment structure is electrically connected to the ground pad.

24. The semiconductor device package according to claim 21, wherein the lateral surface of the encapsulant is substantially coplanar with the end of the portion of the conductive compartment structure.
